(19) United States
(12) Patent Application Publication
(10) Pub. No.: US 2026/0337031 A1
(43) Pub. Date: Oct. 29, 2026

(54) DIAMONDS HAVING ARTIFICIALLY EMBEDDED INCLUSIONS

(71) Applicant: EllansaLabs Inc., Addison, TX (US)

(72) Inventor: Omar Besim HAKIM, Addison, TX (US)

(21) Appl. No.: 19/380,932

(22) Filed: Nov. 5, 2025

Related U.S. Application Data
(63) Continuation of application No. 18/353,864, filed on Jul. 17, 2023, now abandoned.
Application No. 18/353,864 is a continuation-in-part of application No. 18/184,463, filed on Mar. 15, 2023, now abandoned.

(51) Int. Cl. C01B 32/26; A44C 17/00

(52) U.S. Cl. CPC C01B 32/26; A44C 17/006

(57) ABSTRACT

Disclosed herein are synthetic, or cultured diamonds which have at least one artificially embedded inclusion(s) incorporated within their crystal structure during the diamond’s deposition or growth process. Disclosed are cultured diamonds having a substrate portion, artificially embedded inclusion(s) disposed on the substrate portion, and an encapsulating portion, formed on the artificially embedded inclusion(s). The substrate portion and the encapsulating portion are bonded together by covalent carbon to carbon bonds.

### CROSS-REFERENCE TO RELATED APPLICATIONS

This application is a continuation of U.S. Non-provisional Patent Application No. 18/353,864, filed on July 17, 2023, titled “Diamonds Having Artificially Embedded Inclusions”, which is a continuation-in-part (CIP) of U.S. Non-provisional Patent Application No. 18/184,463, filed on Mar. 15, 2023, titled “Diamonds Having Artificially Embedded Inclusions”. The entire contents of both application are hereby incorporated by reference.

### TECHNICAL FIELD

The present specification generally relates to synthetic or cultured diamonds, and more particularly to diamonds having an artificially embedded inclusion incorporated internally within the crystal structure of the diamond, during the synthesis thereof.

### BACKGROUND

Authenticating markings on diamonds are commonly engraved thereon via an inscription which can be placed on an outer layer of the diamond, such as the girdle portion. This is a small external area of the diamond which can be easily manipulated so that the markings, indicia, or authenticating identifiers inscribed thereon can be removed. Embedding images or authenticating indicia internally within gemstones is also known. Commonly this requires that a diamond be cut into two portions, with the markings being laser ablated onto the surface of one portion of the cut diamond, and thereafter joining of the two pieces through a bonding agent or through a bonding process. These methods are not desirable as the bonding agent can affect the clarity and luminosity of the diamond, and can also potentially degrade over time.

Additionally, incorporation of small decorative gemstones within a larger gemstone, currently involves techniques wherein the smaller gemstone is placed within a cavity of an external surface of the larger gemstone. While this provides a pleasing decorative effect, the anchoring and securing of the smaller stone to the larger gemstone can be problematic, and unreliable over time as the smaller stone may become loose or otherwise detach from the larger gemstone.

In light of these drawbacks, there is a need for diamonds that have incorporated therein smaller decorative gemstones, or inclusions such as authenticating markings, inscriptions or other identifying or decorative indicia, which cannot easily be removed and which are incorporated within the diamond in a secure and everlasting manner.

### SUMMARY

Described herein are synthetic, or cultured diamonds which have at least one artificially embedded inclusion(s) incorporated within their crystal structure during the diamond’s synthesis, deposition or growth process.

In one embodiment, a cultured diamond is disclosed. The cultured diamond has
a substrate portion;
at least one artificially embedded inclusion(s) disposed on the substrate portion; and
an encapsulating portion, formed on the at least one artificially embedded inclusion(s)

The substrate portion and the encapsulating portion are bonded together by covalent carbon to carbon bonds. Both the substrate portion and the encapsulating portion are comprised of a diamond and have an un-interrupted, continuous crystal lattice structure which is created during the deposition process of the encapsulating portion onto the substrate portion.

The substrate portion and/or the encapsulating portion are formed by known diamond deposition or synthesis processes. Such processes known in the art include chemical vapor deposition (CVD) methods, such as hot filament chemical vapor deposition (HFCVD) and microwave plasma chemical vapor deposition (MPCVD), or high pressure high temperature (HPHT) process.

In an embodiment, the at least one artificially embedded inclusion comprises human-readable or machine-readable indicia. The indicia, in one embodiment, is an authentication identifier, a QR code, a bar code, an alphanumeric marking, written text, a personalized inscription, an image, a decorative design, a symbol, a pattern, a logo, or a combination of any of the foregoing human-readable or machine readable indicia.

In another embodiment, the artificially embedded inclusion, comprises a secondary gemstone.

In additional embodiments, a cultured diamond is disclosed, the diamond having:
a substrate portion comprising a diamond;
at least one inclusion(s) comprising one or more non-diamond carbon layer (s); and
an encapsulating portion comprising a diamond, formed onto the at least one inclusion(s) and the substrate portion.

The substrate portion and the encapsulating portion are bonded through covalent carbon to carbon bonds. In further embodiments, the at least one inclusion(s) are also bonded to the encapsulating portion through covalent carbon to carbon bonds. In these embodiments, the one or more non-diamond carbon layer(s) refer to deposited graphite layers, deposited graphene layers, deposited amorphous carbon, or graphitized layers.

In another embodiment, a method of embedding an artificial inclusion(s) in a diamond, is disclosed, the method comprising the steps of:
forming a substrate portion comprising a diamond;
disposing at least one artificial inclusion(s) on the substrate porti, and
forming an encapsulating portion comprising a diamond, onto the artificial inclusion and substrate portion.

In one embodiment, the substrate portion and the encapsulating portion are formed by chemical vapor deposition (CVD), hot filament chemical vapor deposition (HFCVD), plasma enhanced chemical vapor deposition (PECVD), microwave plasma chemical vapor deposition, or a high temperature high pressure (HPHT) process. Due to the various steps of the deposition methods described herein, the final formed cultured diamond will have a uninterrupted diamond crystal lattice between the substrate portion and the encapsulating portion, wherein carbon to carbon covalent bonds will be present and hence, these will no longer be considered as separate portions of the diamond but will exist as one unified diamond structure.

In one embodiment the disclosed method, the at least one artificial inclusion(s) comprises a secondary gemstone. The secondary gemstone comprises a gray diamond, white diamond, blue diamond, yellow diamond, orange diamond, red diamond, olive diamond, green diamond, pink diamond, violet diamond, brown diamond, black diamond, garnet, ruby, peridot, sapphire, diopside, emerald, amethyst, topaz, citrine, or a combination thereof.

### Selected Definitions

As used herein, “cultured diamond”, “synthetic diamond”, “lab-grown diamond” or variations thereof refer to a non-naturally formed diamond, which has been grown or synthesized with methods, materials and/or equipment capable of artificially growing diamonds.

As used herein, the term “inclusion”, or “artificial inclusion” or “artificially embedded inclusion”, or variations thereof, refer to a non-naturally occurring structure which has been created within, or placed or disposed within, an internal portion of a diamond, according to embodiments disclosed herein. As used in this disclosure, the term “inclusion” is not to be understood as referring to naturally occurring inclusions in diamond crystal structures, either through natural synthesis of a diamond or through synthetic synthesis of a diamond.

As used herein the term “chemical vapor deposition” or “CVD” or variations thereof refer to a deposition process wherein reactant gases are introduced into a chamber of a reactor or vessel and through various activation media are activated to react and deposit specific species onto a substrate as a solid form deposited material. The use of the term “chemical vapor deposition” is to be understood as comprising all types of chemical vapor deposition processes, including hot filament CVD, plasma enhanced CVD, RF plasma CVD, DC plasma CVD, microwave plasma CVD, and any other known variations of chemical vapor deposition processes.

As used herein, “weight percent,” “wt%, “percent by weight,” “% by weight,” and variations thereof refer to the concentration of a substance as the weight of that substance divided by the total weight of the composition and multiplied by 100.

As used herein, “volumetric percent,” “vol%”, “percent by volume,”, “volume percent”, and variations thereof refer to the relative content of a substance as the mole of that substance divided by the total volume of the composition and multiplied by 100.

As used herein, “g” represents gram; “L” represents liter; “mg” represents “milligram (10⁻³ gram);” “µg” equals to one micron gram (10⁻⁶ gram). “mL” or “cc” represents milliliter (10⁻³ liter). One “µL” equals to one micron liter (10⁻⁶ liter). The units “mg/100g,” “mg/100mL,” or “mg/L” are units of concentration or content of a component in a composition. One “mg/L” equals to one ppm (part per million). “Da” refers to Dalton, which is the unit for molecular weight; One Da equals to one g/mol. The unit of temperature used herein is degree Celsius (°C).

The term “about” is used in conjunction with numeric values to include normal variations in measurements as expected by persons skilled in the art, and is understood to have the same meaning as “approximately” and to cover a typical margin of error, such as ±15%, ±10%, ±5%, ±1%, ±0.5%, or even ±0.1% of the stated value. The term “about” also encompasses amounts that differ due to different equilibrium conditions for a composition resulting from a particular initial composition. Whether or not modified by the term “about,” the claims include equivalents to the quantities.

It should be noted that, as used in this specification and the appended claims, the singular forms “a,” “an,” and “the” include plural referents unless the content clearly dictates otherwise. Thus, for example, reference to a composition containing “a compound” includes having two or more compounds that are either the same or different from each other. It should also be noted that the term “or” is generally employed in its sense including “and/or” unless the content clearly dictates otherwise. As used herein, “and/or” refers to and encompasses any and all possible combinations of one or more of the associated listed items, as well as the lack of combinations when interpreted in the alternative (“or”).

In the interest of brevity and conciseness, any ranges of values set forth in this specification contemplate all values within the range and are to be construed as support for claims reciting any sub-ranges having endpoints which are real number values within the specified range in question. By way of a hypothetical illustrative example, a disclosure in this specification of a range of from 1 to 5 shall be considered to support claims to any of the following ranges: 1-5; 1-4; 1-3; 1-2; 2-5; 2-4; 2-3; 3-5; 3-4; and 4-5.

The term “substantially” is utilized herein to represent the inherent degree of uncertainty that can be attributed to any quantitative comparison, value, measurement, or other representation. The term “substantially” is also utilized herein to represent the degree by which a quantitative representation can vary from a stated reference without resulting in a change in the basic function of the subject matter at issue.

The term “substantially free” may refer to any component that the composition of the disclosure lacks or mostly lacks. When referring to “substantially free” it is intended that the component is not intentionally added to compositions of the disclosure. Use of the term “substantially free” of a component allows for trace amounts of that component to be included in compositions of the disclosure because they are present in another component. However, it is recognized that only trace or de minimus amounts of a component will be allowed when the composition is said to be “substantially free” of that component. Moreover, if a composition is said to be “substantially free” of a component, if the component is present in trace or de minimus amounts it is understood that it will not affect the effectiveness of the composition. It is understood that if an ingredient is not expressly included herein or its possible inclusion is not stated herein, the disclosure composition may be substantially free of that ingredient. Likewise, the express inclusion of an ingredient allows for its express exclusion thereby allowing a composition to be substantially free of that expressly stated ingredient.

The term “comprise,” “comprises,” and “comprising” as used herein, specify the presence of the stated features, integers, steps, operations, elements, and/or components, but do not preclude the presence or addition of one or more other features, integers, steps, operations, elements, components, and/or groups thereof.

As used herein, the transitional phrase “consisting essentially of” means that the scope of a claim is to be interpreted to encompass the specified materials or steps recited in the claim and those that do not materially affect the basic and novel characteristic(s) of the claimed invention. Thus, the term “consisting essentially of” when used in a claim of this invention is not intended to be interpreted to be equivalent to “comprising.”

As used herein, the terms “increase,” “increasing,” “increased,” “enhance,” “enhanced,” “enhancing,” and “enhancement” (and grammatical variations thereof) describe an elevation of at least about 1%, 5%, 10%, 15%, 25%, 50%, 75%, 100%, 150%, 200%, 300%, 400%, 500% or more as compared to a control.

The terms “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the present disclosure.

The above described features and additional embodiments will be described in detail in the sections that follow and are exemplified by the following figures and detailed description.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1A depicts a cross-sectional side view of a cultured diamond during its synthesis process having an artificially embedded inclusion therein

FIG. 1B depicts a cross-sectional side view of cut cultured diamond having an artificially embedded inclusion therein.

FIG. 1C depicts a cross-sectional side view of a cut cultured diamond having a secondary gemstone embedded therein.

FIG. 2A depicts a cross-sectional side view of a cultured diamond, during its synthesis process, as disclosed herein.

FIGS. 2B-2A depicts a cross-sectional side view of a cultured diamond, during its synthesis process, as disclosed herein.

FIG. 2C depicts a cross-sectional side view of a substrate portion of a cultured diamond, as disclosed herein.

FIG. 2D depicts a cross-sectional side view of a substrate portion of a cultured diamond, having a secondary gemstone embedded therein, in accordance with an embodiment of the present disclosure.

FIG. 3A schematically depicts a top view of a round brilliant cut diamond having artificially embedded inclusion therein, in accordance with one embodiment of the present disclosure.

FIGS. 3B schematically depicts a top view of a round brilliant cut diamond having artificially embedded inclusion therein, in accordance with one embodiment of the present disclosure.

FIGS. 3C schematically depicts a top view of a round brilliant cut diamond having artificially embedded inclusion therein, in accordance with one embodiment of the present disclosure.

FIG. 4 shows a phase diagram for carbon indicating main regions of pressure-temperature in which diamond growth occurs.

FIG. 5 depicts a schematic of a hot filament chemical vapor deposition process (HFCVD) and reactor used for diamond synthesis.

FIG. 6 depicts a schematic of a microwave plasma chemical vapor deposition process (MWCVD) and reactor used for diamond synthesis.

FIG. 7A depicts method steps of embedding an artificial inclusion in a diamond, in accordance with an embodiment disclosed herein.

FIG. 7B depicts method steps of embedding an artificial inclusion in a diamond, in accordance with an embodiment disclosed herein.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Described herein are synthetic, or cultured diamonds, which have at least one artificially embedded inclusion(s) incorporated within their crystal structure during the diamond’s synthesis, deposition or growth process.

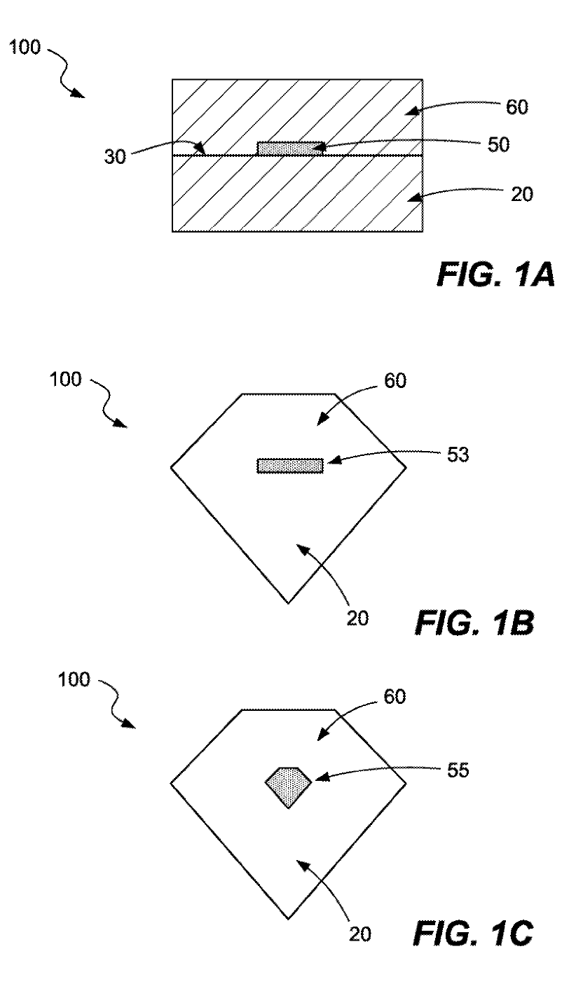

In one embodiment, as depicted in FIG. 1A, a cultured diamond 100 is disclosed. For purposes of this embodiment and following embodiments, the terms “cultured diamond” or “diamond” are used interchangeably and refer to synthetic, or lab-grown diamonds. The diamond 100 has:
a substrate portion 20;
at least one artificially embedded inclusion 50 disposed on the substrate portion 20; and
an encapsulating portion 60, formed on the artificially embedded inclusion 50.

The substrate portion 20 and the encapsulating portion 60 are bonded together by covalent carbon to carbon bonds. That is to say, both the substrate portion 20 and the encapsulating portion 60 are comprised of a diamond and have an un-interrupted, continuous crystal lattice structure which is created during the deposition process of the encapsulating portion 60 onto the substrate portion 20. In a diamond, every carbon atom is covalently bonded to four other carbon atoms and each carbon has a tetrahedral geometry. The substrate portion 20 and encapsulating portion 60 are only described herein as separate structures, not because they are physically separate structures, but because they are temporally separated in their deposition process. Meaning that the substrate portion 20 is formed first during a synthetic diamond deposition process, the process is halted and the at least one artificially embedded inclusion 50 is disposed on the substrate portion 20, then the deposition process can begin gain, wherein the encapsulating portion 60 is thereafter deposited onto and around the artificially deposited inclusion 50 and also onto the substrate portion 20. When the deposition process of the encapsulating portion is occurring, covalent carbon to carbon bonds are formed between the diamond structure of the substrate portion 20 and the diamond structure being deposited as part of the encapsulating portion 60, and as such the two temporally separated depositions create one unitary diamond 100, with a continuous crystal lattice diamond structure, having the artificially embedded inclusion 50 located therein.

The substrate portion 20 and/or the encapsulating portion 60 are formed by known diamond deposition or synthesis processes. Such processes known in the art include chemical vapor deposition (CVD) methods, such as hot filament chemical vapor deposition (HFCVD) and microwave plasma chemical vapor deposition (MPCVD), or high pressure high temperature (HPHT) process.

In a preferred embodiment, both the substrate portion 20 and the encapsulating portion 60, and optionally the at least one artificially embedded inclusion 50 are all formed a by chemical vapor deposition (CVD) process.

In an embodiment, the at least one artificially embedded inclusion 50 comprises human-readable or machine-readable indicia. This can be seen in FIG. 1B, where a human readable or machine readable indicia 53 is embedded within the diamond 100. The indicia 53, in one embodiment, is an authentication identifier, a QR code, a bar code, an alphanumeric marking, written text, a personalized inscription, an image, a decorative design, a symbol, a pattern, a logo, or a combination of any of the foregoing human-readable or machine readable indicia.

When referring to human-readable indicia 53, it is understood that this includes images or text or any form of indicia which is visible to the human eye, either naturally, or through a magnification device or process, including 1X to 100X magnification devices or processes. For example, the human-readable indicia 53 which is artificially embedded within a diamond 100 can include an authentication identifier, a QR code, a bar code, an alphanumeric marking, written text, a personalized inscription, an image, a decorative design, a symbol, a pattern, a logo, which might not be visible to the naked eye, but can be see using a magnifier, a microscope or a jeweler’s loupe or other type of magnification device and technique. For example, a triplet magnifying loupe will provide 10X magnification from which a human-readable indicia, embedded within the diamond 100, can be detected and viewed.

If the indicia 53 which is artificially embedded within the diamond 100 is a machine-readable indicia (also referenced as element 53 in FIG. 1B), such as a QR code, bar code, other type of authentication identifier, a pattern, an alphanumeric code, written text, an image, a decorative design, a symbol, or a logo, this may also be detectable by the human eye, but can also be machine-readable in that it can be scanned and identified through a machine or a scanning system which is designed to scan and identify the indicia. A scanning system can be configured to scan the machine-readable indicia 53, and send a signal a controller indicative of the information of the machine-readable indicia 53. The scanner in this embodiment may be any device or sensor capable of scanning the machine readable indicia 53, such as, for example, a camera, a barcode scanner, or the like. As discussed above, the information contained within the machine-readable indicia 53 can include for example a web address, information regarding the authenticity and/or origin of the diamond 100, or related item that the diamond 100 can be attached to. In embodiments, the information may include a blockchain used for identifying or authenticating information relating to the diamond 100, or related item. Other type of information which will be related to the diamond 100, and available through the scanning of the machine-readable indicia 53 includes, clarity grade or category, cut type, color, origination, dimensional size, chemical makeup, Carat weight, luminosity, inclusions, certifications, ownership, and the like.

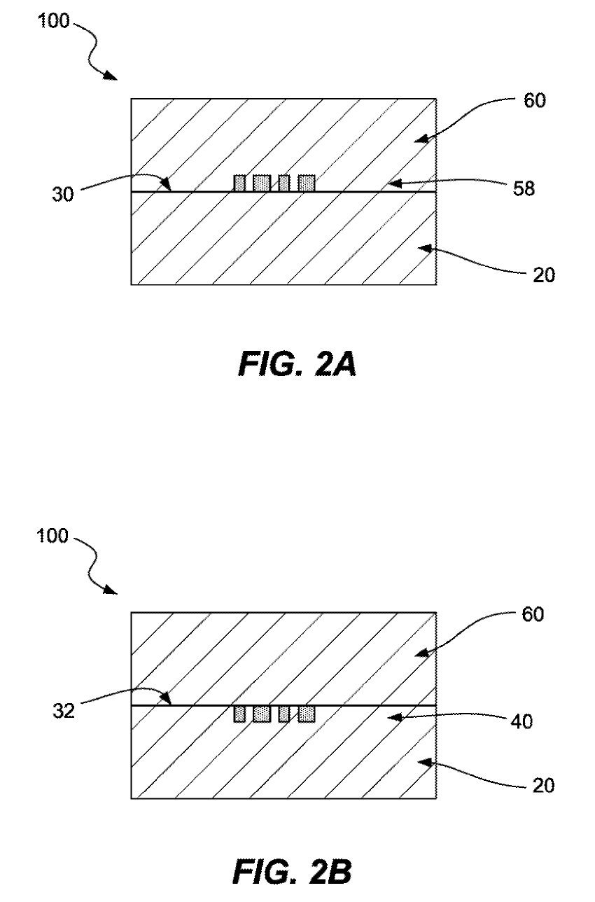

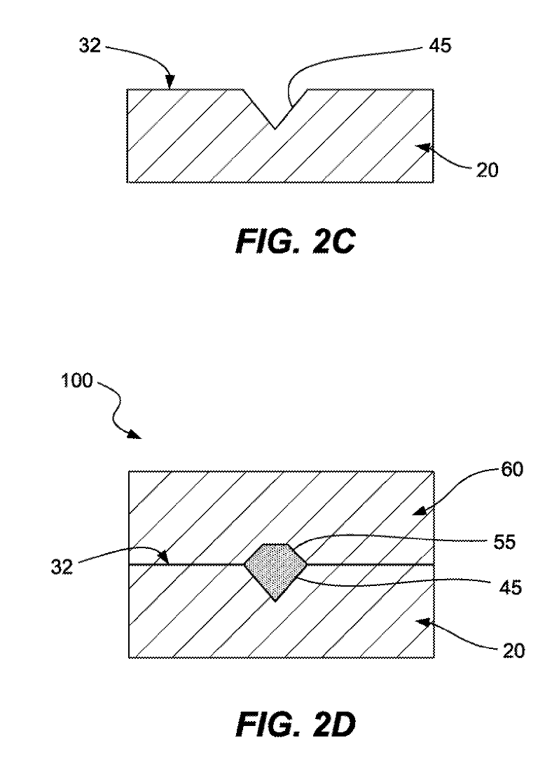

In one embodiment, the human readable or machine readable indicia 53 is comprised of at least one material layer 58 formed on the substrate portion 20. Referring now to the embodiment depicted in FIGS. 2A, a material layer 58 is deposited on a planar surface 30 of the substrate portion 20 of the diamond 100. The planar surface 30 is the upper surface that is created as the deposition process of the substrate portion 20 ends. Once the deposition or synthesis process of substrate portion 20 concludes, the planar surface 30 is available for the deposition of the next layer, the material layer 58. Prior to deposition of the one or more material layer 58, there may be a pretreatment step for the planar surface 30 so as to prepare the surface for the deposition of the one or more material layer 58. Such pretreatment steps will be described in further details in later portions of this disclosure.

In one embodiment, as show in Fig, 2A, the material layer 58 is first deposited as a continuous homogenous layer (not shown), and is subsequently etched or patterned to remove portions of the deposited continuous layer, so that the material layer 58 which remains, forms the human readable or machine readable indicia 53.

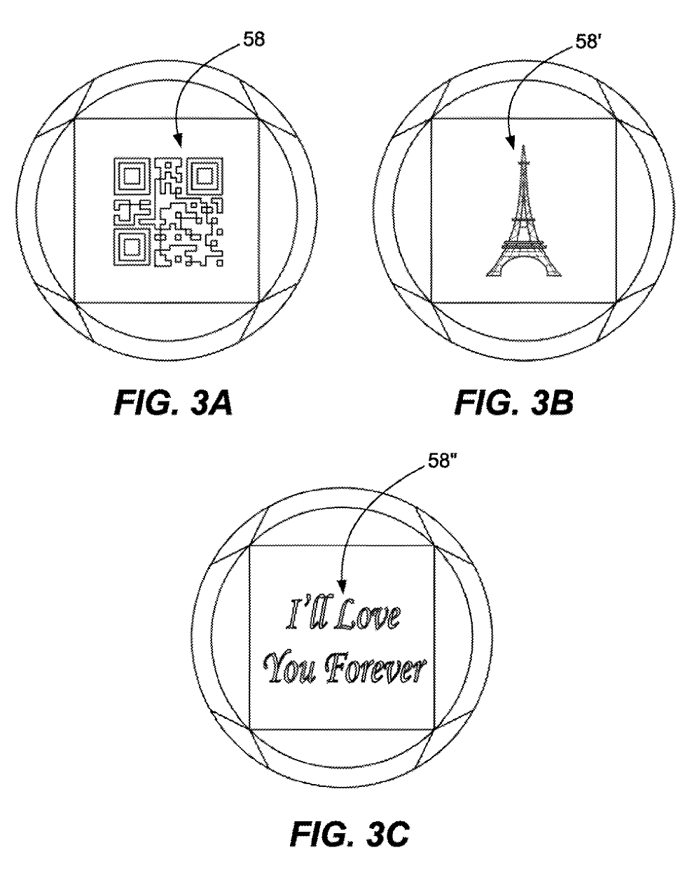

For example, in the embodiment depicted in FIG. 3A, once material layer 58 is patterned into the desired machine readable indicia 53, it takes the final form of a scannable QR code. In a further embodiment, as depicted in FIG. 3B, the material layer 58’ can be etched or patterned so as to form a desired image. Material layer 58’ has been formed to replicate an image of the Eiffel tower. This type of image may be desirable in instances where a specific location is meaningful to the person receiving the diamond. In instances when an engagement happens in a particular iconic location for example, it might be meaningful to the recipient of the diamond to have a commemorative image of the location of the engagement, so that symbolic aspect of that location can be preserved within the image presented in the diamond 100. In an even further embodiment, as can be seen in FIG. 3C, the material layer 58’’ is etched or otherwise patterned to leave a personalized text inscription. The indicia 53 may be sized relative to the size of the diamond 100, such that an increase in the size of the diamond results in an increase in the size of the indicia. It is further contemplated and possible that the indicia 53 may be any size capable of fitting within the diamond 100 and being readable, such as, for example, having a width that is equal to or greater than 0.1 mm, or greater than .25 mm. In a further example, the indicia 53 may be visible and/or scannable with a magnification in a range between 1x and 1000x magnification, such as by a microscope, or between 1x and 10x, such as by a camera on a cell phone. The size of the indicia will thusly vary, and may depend on whether the indicia is meant to be a decorative indicia viewable with the human eye, or if it meant to be an identification or authentication type indicia, in which case it need to be prominently displayed and may have a considerably smaller size, as long as it is capable of being scanned by a scanning device used for machine readable indicia. Although the images of FIG. 3A – 3C display centrally located indicia within a viewing angle from a top portion of the diamond, the indicia 53 may be located in any portion of the diamond and need not be centrally located. The final cut and shaping of the diamond may determine the location of the indicia.

In an embodiment, the material layer 58 is comprised of non-transparent material, including graphite, graphene, a metal oxide compound, a metallic compound, a pigmented compound, or a combination thereof. Metallic compounds that can be incorporated as the material layer 58 are tungsten, gold, platinum, or palladium, or combinations thereof. The metallic compounds can also comprise a refractory metal. Refractory metals to be used can be, but are not limited to, tungsten and molybdenum.

The reason for incorporating the above mentioned materials for the material layer 58, is because indicia such as authentication identifiers, including barcodes, QR codes, or alphanumeric text, requires contrast between the indicia and the background that the indicia is positioned on. For example, a QR code should have a darker appearance than the medium it is printed or disposed on, so that the barcode may be recognizable and/or scannable by a scanning device. Without this contrast, the barcode may not properly be identified by a scanner. Similarly, with human-readable indicia, color contrast will be required between the deposited indicia and the substrate portion 20 or the encapsulating portion 60, for that indicia to be visible and discernable either through the naked eye, or through magnification, as previously discussed above.

Once the material layer 58 has been deposited on the planar surface 30 of the substrate portion 20, it is then formed into the human-readable or machine readable indicia of choice. For example, one or more graphite layers, which can make up the material layer 58, are deposited on the planar surface 30 of a diamond substrate portion 20 (FIG. 2A). This graphite layer then needs to be treated so that the desired indicia can be formed. For example laser ablation, micro-laser inscription, wet etching, ion milling, ion beam irradiation, maskless lithography processes, photoresist masking process, or a combination thereof can be carried out to form the final indicia that is desired. Such methods of forming images or patterns or text on substrates are known in the art.

Alternatively, in another embodiment, instead of depositing a continuous material layer 58, the image or QR code, or barcode, or other desired indicia can be directly formed or printed onto the planar surface 30 of the substrate portion 20. This can be achieved through various techniques known to those skilled in the art, including direct laser writing techniques, such as femtosecond laser micro-marking, microprinting, sputter deposition, additive printing, pulsed laser deposition, laser induced graphitization of an existing diamond surface (using a femtosecond laser), or a combination thereof.

In further embodiments, the deposition of the least one material layer 58, occurs on a non-planar surface 32 of the substrate portion 20. This embodiment is depicted in FIG. 2B, which shows the substrate portion 20, having a non-planar surface 32 formed thereon. The non-planar surface 32 is defined by multiple cavities 40, which are formed onto the surface layer of the substrate portion 20. Instead of first depositing a material layer 58, then using laser ablation or etching to pattern that layer into a desired indicia (FIG. 2A), this embodiment first form grooves 40 within the substrate portion 20, then deposits at least one material layer onto the non-planar surface 32, so as to fill the grooves 40 and form the desired indicia. In this embodiment, it is understood that the grooves 40 which are formed on the surface 32 of the substrate portion 20, are formed in a pre-selected design, including pre-selected text, QR code, barcode, patterned design, logo, image, personalized inscription, or other indicia, prior to the material layer 58 material being deposited to fill the cavities with the previously discussed materials which will ultimately form the human readable or machine readable indicia.

For example, grooves 40 can be formed through laser ablation, micro-laser inscription, wet etching, maskless lithography, a photoresist etching process, or other known patterning techniques known to those skilled in the art that are suitable for creation of indicia on a diamond surface. Once grooves 40 are formed, then the at least one material layer 58 is deposited onto the surface 32 of the substrate portion 20. The material layer deposition can be repeated so that the grooves 40 are filled with the material, up to the surface, or close to the surface boundary of surface 32. A heat treatment process can optionally be conducted so that the material that is deposited within grooves 40, can be sintered or otherwise permanently fixed within the cavities. Thereafter the surface 32 can be pretreated, prior to the deposition process which will form the encapsulating portion 60 on top of and or around the grooves 40, and the substrate portion 20. Pretreatment of the surface 32 can include a cutting step, a cleaning step, a nucleating step, wherein the surface is treated to increase nucleation density or nucleation sites for subsequent carbon bonding during a the deposition process of the encapsulating portion 60, or a combination of said steps. Pretreatment steps for the surface of the substrate portion will be described in more detail in later sections of this disclosure.

Another embodiment is disclosed, wherein a cultured diamond 100 comprises a substrate portion 20, at least one human readable or machine readable indicia 53 disposed on the substrate portion 20, and an encapsulating portion 60, formed on the at least one human readable or machine readable indicia 53.

In embodiments, the human readable or machine readable indicia 53, comprise an image, a logo, a decorative design, a symbol, a pattern, an authentication identifier, a QR code, a bar code, an alphanumeric marking, written text, or a personalized inscription, or a combination thereof. In one embodiment, the human readable or machine readable indicia 53 comprises a logo, a branding identifier, a trademark, or other corporate indicia capable of identifying a specific entity or brand.

In certain embodiments, the human readable or machine readable indicia is comprised of a material layer 58 which incorporates a metallic compound, selected from gold, platinum, silver, tungsten, palladium, or a metal oxide compound, or a pigmented compound, or a combination thereof. For example, the material layer 58 may contain a composition having gold leaf, gold particles, gold containing liquid dispersion, gold containing inks or gold containing pigmented material. In said embodiments, the material layer 58 can be created through either embodiments described in FIG. 2A or 2B, meaning that the material layer can either be deposited or formed on a planar surface 30 of the substrate portion 20, or deposited or formed on a non-planar surface 32 of substrate portion 20 (as depicted in FIG. 2B).

It is envisioned that the metallic compounds which are deposited or formed as part of the material layer 58, for purposes of incorporating the human readable or machine readable indicia, should preferably have a melting point higher than the operating temperature of a CVD diamond synthesis process. For example, if the CVD process for forming the substrate portion and encapsulating portion of the diamond is carried out at a temperature range of about 700-1000 °C, then it is preferable that the deposited material layer on the substrate portion 20 has a higher melting point than 700-1000 °C. This results in a stable material layer, which is not temperature compromised during the deposition process of the encapsulating portion 60, which follows the deposition of the material layer 58.

In one embodiment, cavities 40 are formed on the surface of the substrate portion 20, in the desired shape and size of the particular indicia chosen, such as for example a logo or a trademark. A material layer is then applied in the cavities, to fill the cavities with the chosen material, for example a gold-containing material, dispersion, powder, paste, or liquid. Once the material layer is deposited within the cavities 40, then an optional treatment step can be performed to sinter, or solidify the metallic material within the cavities. This can include a heating or other thermal treatment step, or combination of steps. Once the material layer is solidly deposited within the cavities, the deposition of the encapsulating portion can commence. Optional intervening cleaning steps or nucleating steps can also be incorporated prior to the deposition of the encapsulating portion, to ensure clean surface and/or nucleated surface for diamond deposition.

In other embodiments, the least one human readable or machine readable indicia disposed on the substrate portion comprises a material layer which contains luminescent, fluorescent or phosphorescence materials. These materials will appear optically transparent to the naked eye, but are capable of fluorescing, once excited with a light source at a particular wavelength. These materials have the ability to absorb light of a specific wavelength and emit light of a different wavelength. Specifically with fluorescent materials, the fluorescent emission takes place immediately when the excitation light source is provided to the material and will only last while the material is absorbing the light source. Once the light source is terminated, the fluorescent material is no longer visible. Phosphorescent materials are capable of emitting light after the excitation source has terminated and will have lingering afterglow that will persist for a period of time after the light source is removed.

In one embodiment, the least one human readable or machine readable indicia disposed on the substrate comprises a material layer comprising fluorescent diamond particles. Preferably, the fluorescent diamond particles have point defects in their crystal lattice structure, also sometimes referred to as color centers. These lattice defects are present due to non-carbon atoms in the diamond crystal structure. For example, one such well-known defect incorporates nitrogen atoms. When nitrogen is incorporated into the synthesis of CVD diamonds it can result in substitutional defects of the carbon-to-carbon bonding in diamond lattice structure. These point defects result in unique optical properties, including increased luminescence/fluorescence.

In one embodiment, fluorescent diamond particles are used in the material layer which have a nitrogen-vacancy defect (N-V). In other embodiments, the fluorescent diamond particles have a nitrogen-vacancy-nitrogen defect (N-V-N). In a further embodiment the fluorescent diamond particles have a N₃ vacancy defect. The material layer containing the fluorescent diamond particles, can either be deposited as a planar layer on the substrate portion, e.g.. a deposited film layer, which is then etched or otherwise removed in a post-processing step to create a desired indicia on the substrate portion. Alternatively, the material layer can be placed within preformed cavities 40, according to embodiments already described with respect to FIG. 2B. Once the fluorescent diamond particles material layer is disposed on the non-planar surface containing the cavities (in a desired configuration), then the process of forming the encapsulating portion 60 of the diamond 100 can commence.

In one embodiment, the fluorescent diamond particles incorporated within the diamond 100 have only one type of vacancy defect, i.e. all the particles have the N-V defect. In other embodiments, the fluorescent diamond particles have a combination of defects disclosed herein.

In some embodiments the human readable or machine readable indicia disposed on the substrate comprises a combination of different indicia, comprised of different materials. For example within a single diamond 100 structure, multiple indicia are envisioned, with one having a graphene or graphite material, another indicia comprised of a metallic material (as described in embodiments above) and optionally other indicia comprising fluorescent diamond particles.

The fluorescent diamond particles preferably have a high concentration of vacancy defects, i.e. color centers. Methods for preparing such particles are already known in the art, and such particles are also commercially available. These particles can comprise other types of defects, not limited to nitrogen related defects, for example boron, phosphorous, hydrogen, silicon, germanium, tin or a combination thereof. In a further embodiment, the diamond 100, once synthesized, further comprises a surface coating, which is optically transparent, but has comprises fluorescing materials. For example, the coating can comprise compounds which fluoresce at particular wavelengths (i.e. particular color) under ultraviolet (UV) light.

Also disclosed are cultured diamonds, which incorporate a dopant material during their synthesis process. More specifically, in one embodiment, a cultured diamond 100 comprises a substrate portion 20, at least one human readable or machine readable indicia disposed on the substrate portion 53 and an encapsulating portion 60, formed on the at least one human readable or machine readable indicia. In this embodiment, the substrate portion and encapsulating portion comprise a dopant material and are bonded by covalent carbon to carbon bonds during their synthesis process.

In these embodiments, the substrate portion and encapsulating portion comprising the dopant material are deposited or formed using any of the CVD methods, disclosed herein and known in the art. A dopant material is incorporated into the feed gas during said synthesis process. For example, the dopant material comprises any of nitrogen, boron, phosphorous, hydrogen, silicon, germanium, tin or a combination thereof. Other dopants can also be incorporated which are known to contribute to vacancy defects in the lattice structure of diamond materials during or post diamond synthesis.

The dopants disclosed herein can be incorporated during a synthesis process by introducing a dopant-containing gas, in addition to the carbon source gases typically utilized in diamond deposition. For example, in addition to a methane and hydrogen gas, ammonia gas (nitrogen-containing gas) can also be introduced into the reactor during a deposition process. Molecular nitrogen containing gas source could also alternatively be used. Preferably, the source gas of the dopant is incorporated in sufficient amounts, so as to result in incorporation of nitrogen atoms within the diamond structure. For example, Nitrogen can be combined in the source gases at a concentration of 100 ppm to 500 ppm, of the total gas feeds in a CVD reactor.

In one embodiment, a post synthesis treatment comprising ion beam irradiation and/or thermal treatment can be carried out on a cultured diamond 100. Ion beam irradiation and thermal treatment methods are both known to create or increase vacancy defects in diamond structure. For example, irradiation and thermal annealing can be carried out once a diamond 100 has been synthesized. These methods result in the formation of color centers due to nitrogen vacancy (N-V) defects, or nitrogen-vacancy-nitrogen (N-V-N) defects, or N3 defects, as previously described above. In some embodiments, the nitrogen-vacancy defect comprise negatively charged nitrogen-vacancy defect, neutral nitrogen-vacancy defects, or a combination thereof. This is of course the case in the instance where nitrogen is used as a dopant material. In one embodiment, electron ion beam irradiation is performed, as a post-synthesis treatment. In other embodiments, thermal treatment of the cultured diamond is performed at a temperature between 700° C and 1000° C. These two post-synthesis-treatment steps can be combined or used singularly. Ion beam irradiation and thermal treatment methods are known in the art to impart defects in the diamond structure.

In other embodiments, the dopant materials utilized during the diamond synthesis process comprise boron, phosphorous, hydrogen, silicon, germanium, tin or a combination thereof. The incorporation of each of these dopants is known in the art, and various techniques will be apparent to those of skill in the art. For example, incorporation of boron dopants into diamond deposition processes can be carried out by incorporating a boron source gas in the CVD deposition process. For example, diborane B₂H₆ can be used, or a boron containing rod can be placed in the plasma section of a plasma assisted CVD process, or a boron containing powder dispersed in the CVD chamber during deposition. A combination of dopants can also be used, such as for example nitrogen and boron, or any other dopants known to cause vacancy defects, during deposition or through post treatment methods.

It is envisioned that when a dopant material is utilized for the synthesis and deposition of the substrate and/or encapsulating portions of the diamond 100, such material should be uniformly used during the growth process, so that the vacancy defects are present throughout the whole structure of the diamond 100. CVD processes for incorporating dopants into diamond structures can be utilized, such as those described in US Publication No. 2007/0092647 A1, the relevant parts of which are incorporated herein by reference.

In other embodiments, a culture diamond is synthesized which does not comprise human or machine readable indicia. For example, in one embodiment a cultured diamond is disclosed, comprising a substrate portion, an encapsulating portion and at least one dopant material. The dopant material imparts vacancy defects within the cultured diamond. In one embodiment, the substrate portion and encapsulating portion can be deposited in a single continuous CVD deposition process. Therefore in this embodiment, a cultured diamond is created having a dopant material dispersed throughout, and the process of deposition is not halted, but rather both the substrate portion and encapsulating portion are formed in a single step, resulting in a single unified diamond structure, having the dopant material uniformly dispersed through its lattice structure, but not having any embedded layer in between or indicia formed during the deposition process. The dopant material is incorporated during the deposition and growth process in order to impart vacancy defects in the diamond structure, which result in color centers capable of fluorescence when excited with a light source at a specific wavelength.

In other embodiments, the at least one dopant material can be present in the cultured diamond as a deposited material layer, which is deposited on the substrate portion, once the substrate portion is formed and prior to deposition of the encapsulating portion. The deposited material layer comprises fluorescent diamond particles, in one embodiment. The deposited material layer can be produced onto the substrate layer to cover the entire area of the substrate portion, or it can be incorporated in a part of the substrate portion. The encapsulating portion is then deposited thereon. Various intermediary processing steps including cleaning, heating, or nucleating steps can be carried out as disclosed throughout the above embodiments. In said embodiments where the fluorescent diamond particles are applied as a material layer onto the substrate portion, it is evident that the dopant material is contained within the fluorescent diamond particles (as described in prior embodiments).

The at least one dopant material comprises nitrogen, boron, phosphorous, hydrogen, silicon, germanium, tin or a combination thereof. The dopant material causes vacancy defects which result in color centers that exhibit fluorescence when excited with a light source at specific wavelengths. Thus, the color centers which are capable of fluorescence can be incorporated entirely throughout the whole diamond, during the single continuous deposition process disclosed above, or they can be incorporated through the deposited material layer, which is applied onto the substrate portion, during the deposition process.

In an embodiment, due to the specificity of the dopant materials incorporated therein, the diamond 100 exhibits fluorescence, when exposed to a specific excitation wavelength from a light source. This fluorescence can be detected using optical instruments with an integrated detector tuned to a specific wavelength range. Alternatively, the fluorescence can be detected using the naked eye, depending on the fluorescence output and intensity due to the type of dopant and amount of dopant incorporated during the synthesis process.

Moving now to other embodiments of the present invention, diamonds having an artificially embedded inclusion 50, comprising a secondary gemstone, are disclosed. As can be seen in the embodiment depicted in FIG. 1C, a secondary gemstone 55 is incorporated into the diamond 100 internal crystal structure, with methods which will be further described herein. In embodiments, the secondary gemstone 55 comprises a diamond, such as a gray diamond, white diamond, blue diamond, yellow diamond, orange diamond, red diamond, olive diamond, green diamond, pink diamond, violet diamond, brown diamond, black diamond, or other color variation of diamond known in the art. The secondary gemstone can be a naturally occurring gemstone, or a synthetic cultured gemstone. In further embodiments, the secondary gemstone 55 is garnet, ruby, olivine, peridot, sapphire, diopside, emerald, amethyst, topaz, citrine or other known gemstones, including precious stones, semi-precious stones, quartz formations, or a combination thereof.

In one embodiment, prior to a secondary gemstone 55 being embedded within the crystal lattice structure of diamond 100, it may require pretreatment in order to increase nucleation sites and/or nucleation density. Diamond crystal structures do not typically grow on non-diamond materials, unless there is a nucleation enhancement step, to increase the availability of carbon bonding sites, so that a diamond crystal lattice structure can be grown/deposited and the required covalent carbon to carbon bonds can form. This step is also sometimes also referred to as seeding. Nucleation is generally a thermodynamically driven process where clusters of atoms or nuclei evolve to form stable phases. In non-diamond substrates, such as the secondary gemstones, disclosed herein, pretreatment for the increase of nucleation sites and/or density can be achieved by methods including, electrostatic seeding with diamond nanoparticles, polishing with diamond grit, chemical nucleating solutions, comprising for example adamantane powder, mechanical surface roughing, or other known techniques, which will be understood by those skilled in the art as increasing the nucleation sites of non-diamond substrates to achieve diamond deposition and carbon-carbon covalent bond formation.

One of the most successful seeding techniques for growth of nanocrystalline diamond on non-diamond substrates is the electrostatic seeding technique, which utilizes diamond nanoparticles. In this process a non-diamond substrate is coated with diamond nanoparticles before growth or deposition of a diamond layer. For example, once the coated substrate is exposed to CVD conditions, individual diamond crystals will start to grow. At the beginning, the growth may be localized to specific individual crystal or islands, and as the deposition process continues, the islands become big enough to coalesce and show columnar crystalline growth, and bulk diamond deposition can be achieved. Generally the substrates are coated with the nanocrystalline diamond seed by dipping in a seed containing solution or by electrospraying, or by and spin-coating the solution onto the non-diamond substrate.

In some embodiments, the pretreatment step can enhance nucleation through mechanical surface roughening or polishing of the secondary gemstone 55, using diamond grit. For example, the secondary gemstone 55 may be hand polished with a diamond paste. The diamond paste can contain diamond particles of micron size, such as particles of 1–20 μm, or 5-10 μm. While not intending to be bound by theory, it is believed that the mechanical surface roughening by polishing with diamond particles, causes nano or micron sized defects on the surface of the substrate being treated and also lodges small diamond particles within these defects, which in turn increases the nucleation density or nucleation sites for future diamond deposition.

In another embodiment, the pretreatment step can include the use of a chemical nucleating solution to induce chemical nucleation sites. This can be accomplished for example through the use of a solution comprising what are known as diamondoids. Diamondoids are molecules which are also sometimes referred to as nanometer-sized diamond molecules, with one such example being adamantane, which is available in a polycrystalline powder form. The adamantane powder is dissolved in a solution of hexane or ethanol and the non-diamond substrate, i.e. the secondary gemstone 55, can be sonicated in the solution prior to deposition. After sonication the substrate is washed in ethanol, prior to being introduced in a CVD reactor for diamond deposition thereon.

Referring now to FIGS. 2C-2D, a further embodiment will be described, wherein the secondary gemstone 55 is incorporated onto a cavity 45 formed onto the substrate portion 20. The cavity 45 is incorporated onto the surface of the substrate portion 20, thereby resulting in a non-planar surface 32. The shape of the cavity 45, although shown as “V”-shaped in the depiction of FIG. 2C-2D, can take any shape and is preferably formed in the shape corresponding to the secondary gemstone 55 that is to be placed therein. As can be seen in the embodiment shown in FIG. 2D, the secondary gemstone 55, is disposed and fits within the cavity 45, in a corresponding shape, and is thus physically anchored therein. Prior to the placement of the secondary gemstone 55 within the cavity 45, a bonding agent can be applied to the cavity so that the securement of the gemstone 55 can be assured. This is however not a required step. By placing the secondary gemstone 55 within the cavity 45, the gemstone is mechanically anchored and oriented within the substrate 20, so that the deposition of the encapsulating portion 60 can be carried out and the secondary gemstone 55 is secured and stable during the deposition process. Because the gemstone has been pretreated to increase nucleation sites and/or nucleation density, once it is exposed to a CVD chamber and with reactant gases, deposition of a diamond layer will occur on the secondary gemstone 55 surface, and on the surface of the substrate portion 20, thereby forming carbon-to-carbon covalent bonding with both the diamond surface of the substrate portion, and also the non-diamond surface of the gemstone 55. In some embodiments where the secondary gemstone 55 is also a diamond, a pretreatment step for enhancing nucleation is also carried, out to ensure proper bonding and crystal lattice formation during deposition of the encapsulating portion 60. Additionally, in some embodiments, the surface 32 of the substrate portion 20 is also pretreated for cleaning and for nucleation enhancement, prior to deposition of the encapsulating portion 60. The surface of the substrate 20 may be polished or cut so as to create an atomically flat surface. For example, during laser etching or milling to create the cavity 45, various debris may be deposited, or damage may be caused to the surface of the substrate portion 20. As such, it may be preferred to clean and pretreat the surface prior to placing the substrate portion 20 back into a CVD deposition chamber for growth of the remaining encapsulating portion 60.

As previously disclosed, the encapsulating portion 60 is deposited onto the secondary gemstone 55 and onto the substrate portion 20 by any known diamond deposition or diamond formation process, such as chemical vapor deposition (CVD), which includes hot filament chemical vapor deposition (HFCVD) and microwave plasma chemical vapor deposition (MPCVD). Alternatively, an HPHT process can also be used to form either the substrate portion 20, the encapsulating portion 60, or both.

In further embodiments, the artificially embedded inclusion(s) can include not only secondary gemstones and indicia, but a combination of both, including at least one secondary gemstone and at least one human readable or machine readable indicia. The location of said inclusions can vary. For example, a machine readable inclusion can be created in a layer which is close to the surface portion of the final cut diamond, while a secondary gemstone can be incorporated to be centrally located within the final diamond 100, or can be in a lower location from the table of the final diamond 100. The inclusions can be spatially separated, so that when viewing the diamond from a top portion, all inclusions are viewable and do not overlap. Alternatively, if a decorative pattern is being formed, some overlap of various inclusions may be desirable to create specific three dimensional pattern within the diamond 100. Therefore, it is envisioned that the inclusions can be incorporated at any part of the diamond 100 structure, and in various layers, although in the Figures they are displayed as being located centrally within the diamond 100. This is for illustration purposes only and is not intended to be a limiting orientation, or location or placement within the diamond 100.

In additional embodiments, a cultured diamond 100 is disclosed, the diamond having:
a substrate portion comprising a diamond;
at least one inclusion(s) comprising one or more non-diamond carbon layer (s); and
an encapsulating portion comprising a diamond, formed onto the at least one inclusion(s) and the substrate portion.

The substrate portion and the encapsulating portion are bonded through covalent carbon to carbon bonds. In further embodiments, the at least one inclusion(s) are also bonded to the encapsulating portion through covalent carbon to carbon bonds. In these embodiments, the one or more non-diamond carbon layer(s) refer to deposited graphite layers, deposited graphene layers, deposited amorphous carbon layers, or graphitized layers.

Graphitized layers are not deposited but rather formed from a graphitization process which turns layers of the existing diamond crystal structure of the substrate portion 20 into a graphite sp2 carbon layer(s). Graphitization of a diamond surface layer can be achieved by methods known in the art, such as for example using high pressure high temperature (HPHT) processing of layers in diamond created by focused ion beam (FIB). Graphitized layers can also be created by use of laser irradiation, or pulsed laser irradiation. It is known that focused laser radiation can initiate processes that lead to laser modification of diamonds crystal structure, while using powerful nanosecond, picosecond, and femtosecond lasers operating in the ultraviolet, visible, and infrared ranges. For example, a commercial Ti:sapphire laser can be used to produce pulse widths of 120 femtoseconds (fs) of wavelength of 800 nm. 400 nm, 266 nm, or 200 nm. The surface of the diamond is irradiated with these pulsed parameters at said wavelengths to create graphitization of surface layers of the diamond. This is in essence is a process by which micro-restructuring of carbon layers occurs as a result of local graphitization of the surface due to single- or multi-photon absorption (depending on the laser quantum energy) of powerful laser radiation, which causes the ionization of the sp3-carbon material, resulting in sp2 carbon structures, i.e. graphite formation.

In addition to a graphitized layer, the one or more non-diamond carbon layer(s) refer to carbon containing layers, which are either graphite containing layers, graphene containing layers, or amorphous carbon containing layers. The carbon containing layers can be deposited by known methods, including by chemical vapor deposition methods. For example, the substrate portion, once formed can be prepared for deposition of a graphite layer thereon. This graphite layer can be deposited either in the same CVD reactor where the substrate portion was grown, or in another CVD reactor, or in another type of equipment, using a process capable of depositing graphite layers on diamond substrates. In one embodiment, a CVD reactor is used to deposit the non-diamond carbon layer(s). Reactant gases, including methane and hydrogen enter the CVD reactor, while the reactor is maintained at the appropriate temperatures and pressures for non-diamond species deposition.

One such way of forming graphite layers on substrates is through the deposition of a multitude of graphene layers. Graphene is considered the basic building-block of graphitic materials, and is a two-dimensional, single-atomic layer carbon material consisting of six bonded sp2 carbon atoms that are tightly-packed in a honeycomb lattice. Multiple stacked graphene sheets form a three-dimensional graphite structure. Graphene can be deposited in a CVD reactor using carbon rich gas sources, such as methane. Graphite layers can therefore be formed during sustained multi - graphene layer deposition process, which is stopped once the desired film growth has been reached. The film growth for these layers may be several nanometers or several microns in height. In one embodiment the non-diamond carbon layer has a height of about 0.1 microns to about 10 microns. Or about 0.5 microns to about 8 microns, or about 1 micron to about 6 microns, or about 2 microns to 5 microns, or about 3 microns to 4 microns or any range or value therebetween.

Graphite layers are typically grown when the substrate of deposition is heated above 900 °C. A carbon rich methane reactant gas in the presence of H2 and Argon diluting gases can be used, while the substrate portion is kept at high temperatures, such as above 900 °C. The volumetric gas percentages of the reactant gas mixtures will be tailored so as to be optimal for graphite growth, in addition to the reactor pressure and temperatures. Such methods of CVD graphite deposition on carbon containing substrates are known in the art. Other known methods of creating graphite layers include spray coating with a commercially available graphite containing spray, or coating with suspension of graphite platelets prepared by ultrasonic liquid phase exfoliation (LPE), or by abrasion of the surface with high purity graphite powder. Once the deposition of the graphite containing material, whether it be a coating or powder, an annealing step can be conducted using a focalized laser beam, wherein the deposited graphite is then annealed on the surface it has been deposited on. The laser is raster-scanned over the area to be annealed, allowing, for example, spatially variable annealing. With a localized laser spot, a significant amount of heat can be generated on the film in a short amount of time without damaging the substrate underneath. Annealing of deposited graphite layers can also be achieved through heating, such as for example in a furnace, operated at high temperatures, effective for annealing a graphite layer.

In some embodiments, a graphite powder coating can be applied to the substrate portion 20, prior to graphite deposition, or as a part of the graphite deposition step. This graphite powder coating can be annealed onto the surface in a subsequent heating step. During the graphite deposition process, the graphite powder coating can serve as a nucleating layer for further graphite growth during a CVD process, or the graphite powder coating can make up the non-diamond coating layer itself, such that no further CVD process is required and only a coating step is undertaken. A graphite powder coating can be applied to the substrate portion, wherein the coating comprises graphite powder mixed in an alcohol solution. Once the graphite containing solution is applied on the surface of the substrate portion, it can be annealed using high temperatures, wherein the graphite powder remains on the surface an all other species are sintered and or evaporated from the coating.

The graphite layer can then be patterned through laser etching, chemically etching, laser milling, or otherwise removed using a masked or non-masked process (for example using a masking or photoresist process), or otherwise treated so as to create the desired final indicia on the surface of the substrate portion, prior to the final deposition of the encapsulating portion thereon.

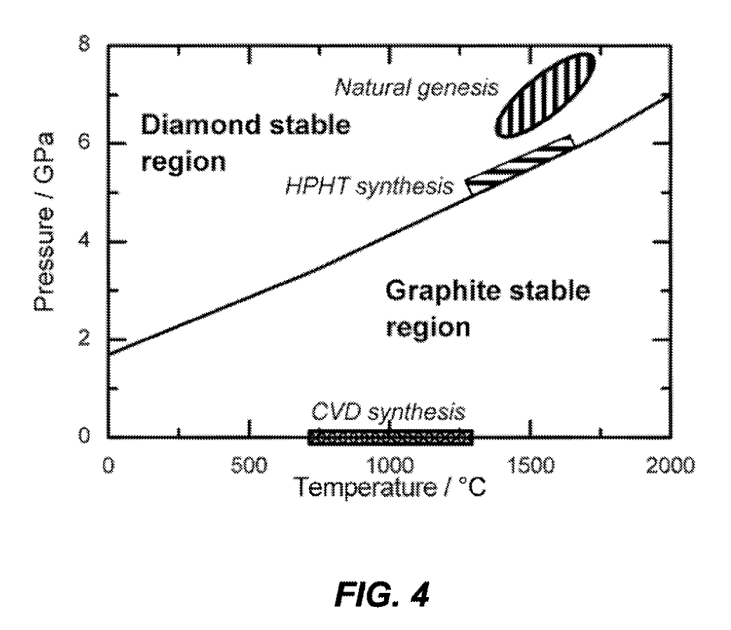

Shown on FIG. 4 is a phase diagram for carbon indicating the main regions of pressure-temperature parameters in which diamond growth can occur. As noted previously, growth of a cultured diamond is typically achieved through CVD processes or through high pressure high temperature process (HPHT). The phase diagram shown in FIG. 4 outlines the pressure and temperature levels for CVD diamond growth and also for HPHT diamond growth. It is notable that CVD deposition processes are low pressure processes, i.e. they happen low pressures or atmospheric pressures, but high temperatures in the region of 700 to 1200 °C. Whereas HPHT diamond growth happens in highly pressurized vessel or chamber, also at extremely high temperatures, which mimics the temperature/pressure parameters of natural diamond formation as it occurs in the earth.

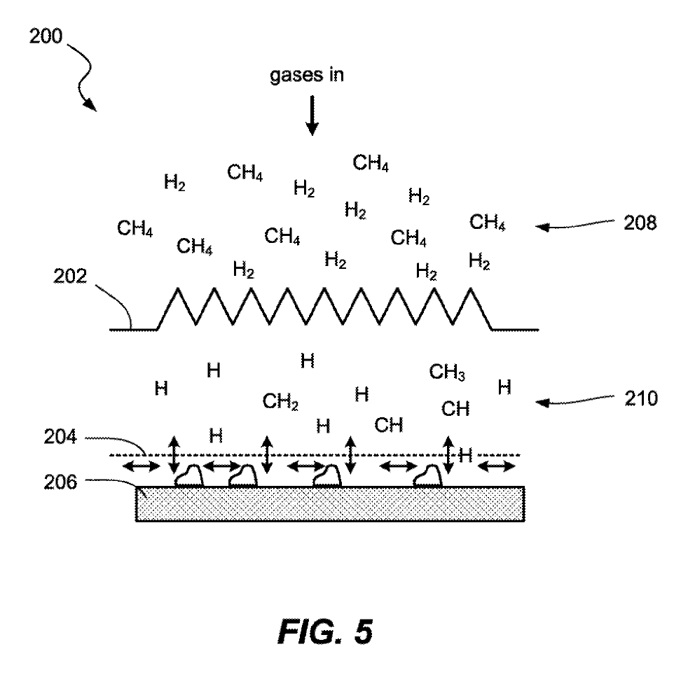

A schematic of the general elements of a CVD process for diamond growth is shown in FIG. 5. Reactant gases (208) methane CH4 and hydrogen H2 enter the reactor. A hot filament 202 is placed in the path of the reactant gases and near a substrate 206 where deposition and growth will occur. Diamond seeds are placed onto the substrate 206.The filament 202 is heated by passing an electrical current through the filament. The temperature in the deposition chamber is measured by a thermocouple in contact with the substrate holder. The gas mixture of reactant gases 208 diffuses onto the filament and the gas species dissociate into free radicals 210 and form a deposit on the substrate 206 placed below the filament at a distance of about 2-8 mm. The entire process is carried out at low pressures (20-40 torr), and the deposition rate for high-quality diamond films is typically about 1 µm/hr.

The mixture of methane and hydrogen is tailored to yield optimum carbon deposition for diamond growth. The carbon content for deposition onto the diamond seeds comes from the carbon containing gas, methane. Other carbon containing gases, such as acetylene can also be used. Atomic hydrogen is believed to be the most critical determinant of diamond film quality and the growth rate. It is involved in the formation of carbon-containing radical species and the production of H-C bonds on the growing diamond surface, preventing it from reconstructing to a graphite-like structure. Atomic hydrogen also etches the film surface, taking away both diamond and graphite. Under typical CVD conditions, the rate of diamond growth exceeds its’ etch rate which does not happen for other carbon structures, and only diamond film remains. Typically the content of methane will be low, for example, 0.3% to 5.0% (volume %), or more preferably 0.5% to 2.5 %, as compared to the hydrogen introduced into a CVD reactor.

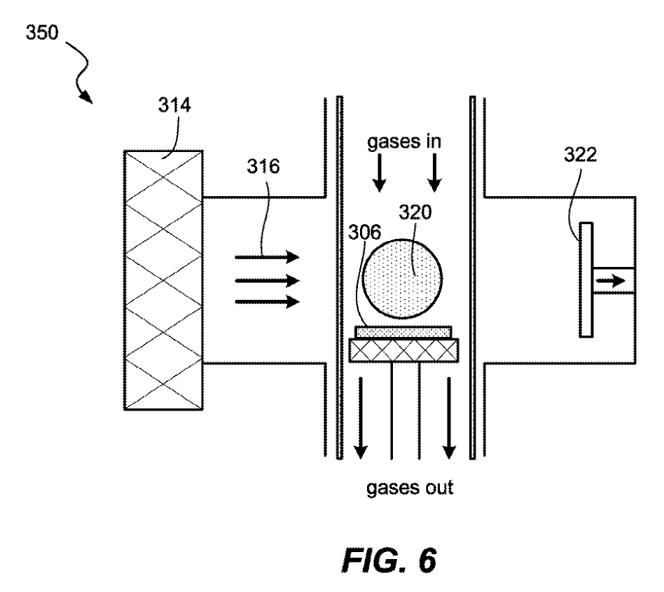

FIG. 6 is a schematic of a microwave plasma CVD process and equipment 350 which is known and commonly used to synthesize diamond structures. Microwave plasma CVD uses electric discharge to produce the radicals necessary for diamond growth. In MWCVD, the microwave power is generated (microwaves) is coupled into the growth chamber via a quartz window in order to generate a plasma discharge. According to the design and the size of the chamber cavity, only one microwave mode is permitted in order to create one plasma ball 320 directly above the substrate 306 surface. The microwave energy 316 is transferred to electrons which oscillate and accelerate the incoming the gases, the free radicals are formed and solid species deposition occurs onto diamond seed(s) located on the substrate 306 which typically is placed within about a millimeter of the generated plasma ball 320. The ionization from the plasma essentially splits molecular bonds within the gases, and the pure carbon is deposited and adheres to the diamond seed(s) and slowly builds up into a larger crystal, atom by atom, layer by layer.

Alternatives to chemical deposition methods, HPHT methods used an entirely different process and equipment for diamond growth. In an HPHT process, a diamond seed is placed in a specifically designed press chamber. The chamber is heated to 1300-1600 °C with pressures above 870,000 pounds per square inch and has within carbon starting material, such as for example graphite. Within the capsule, a carbon starting material, dissolves in a molten flux consisting of metals such as iron (Fe), nickel (Ni) or cobalt (Co), which lowers the temperature and pressure needed for diamond growth. The carbon material then migrates through the flux towards the cooler diamond seed and crystallizes on it to form a synthetic diamond crystal. Crystallization occurs over a period of several days to weeks to grow one or several crystals.

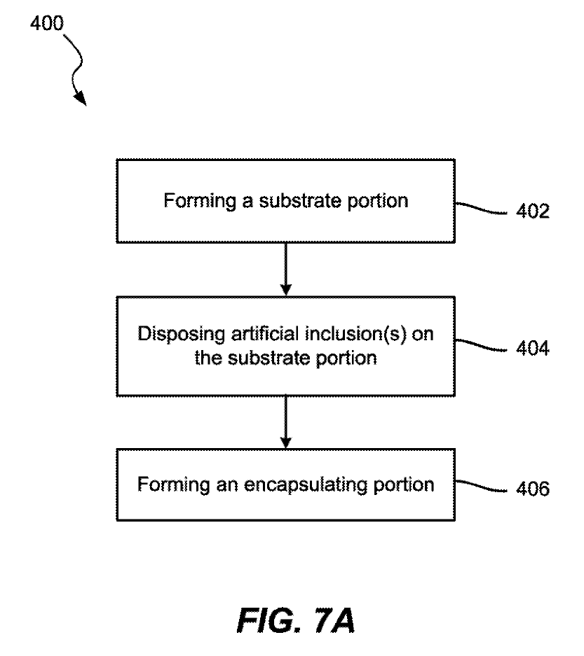

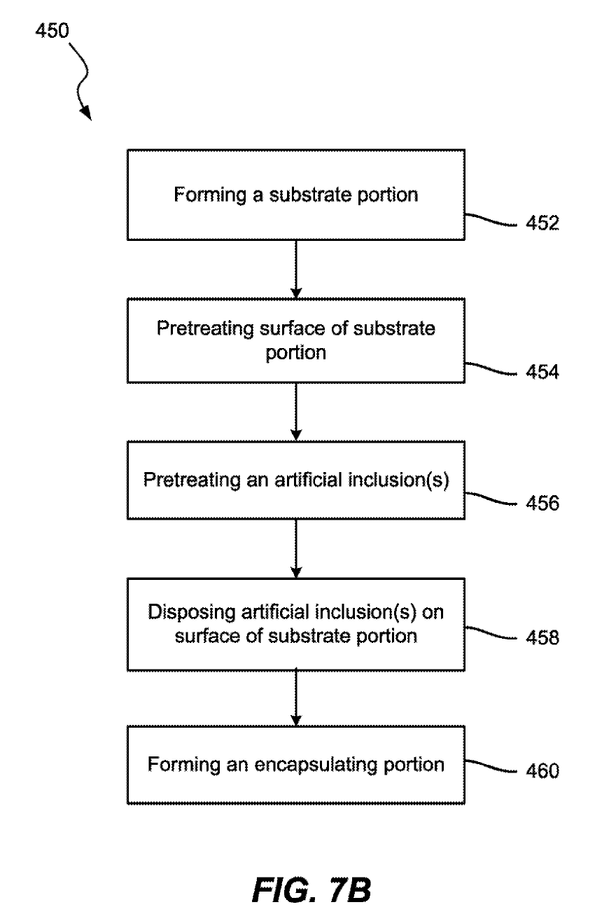

Methods will now be described to with respect to embodiments of embedding artificial inclusion(s) in a cultured diamond 100. Methods are depicted in sequential steps, as for example in the embodiment shown in FIG. 7A. A method 400 of embedding an artificial inclusion(s) in a diamond, is disclosed, the method comprising the steps of:
forming a substrate portion (402) comprising a diamond;
disposing at least one artificial inclusion(s) on the substrate portion (404); and
forming an encapsulating portion (406) comprising a diamond, onto the artificial inclusion and substrate portion.

In one embodiment, the substrate portion and the encapsulating portion are formed by chemical vapor deposition (CVD), hot filament chemical vapor deposition (HFCVD), plasma enhanced chemical vapor deposition (PECVD), microwave plasma chemical vapor deposition (MPCVD), or a high temperature high pressure (HPHT) process. Due to the various steps of the deposition methods described herein, the final formed cultured diamond will have a uninterrupted diamond crystal lattice between the substrate portion meets the deposited encapsulating portion, wherein carbon to carbon covalent bonds will be present and hence, these will no longer be considered as separate portions of the diamond but will exist as one unified diamond structure.

The step of forming a substrate portion (402) comprising a diamond is for example carried out through any suitably CVD process, which are known to those skilled in the art. For example, one such process is outlined in US published patent applications US 2017/0009376A1, to Khal et al., the relevant contents of which are incorporated herein by reference. The step of forming an encapsulating portion (406) can also carried out using the same method and/or parameters as the formation of the substrate portion.

In one embodiment the disclosed method, the at least one artificial inclusion(s) comprises a secondary gemstone. The secondary gemstone comprises a gray diamond, white diamond, blue diamond, yellow diamond, orange diamond, red diamond, olive diamond, green diamond, pink diamond, violet diamond, brown diamond, black diamond, garnet, ruby, peridot, sapphire, diopside, emerald, amethyst, topaz, citrine, or a combination thereof.

In another embodiment, a method 450 as shown in FIG. 7B is disclosed. This method 450 incorporates steps 402, 404 and 406 of the previously described method 400, with the addition of pretreatment steps 454 and 456. After formation of a substrate portion, an optional pretreatment step 454 is conducted for the surface of the substrate portion. Additionally a pretreatment step 456 is conducted for the artificial inclusion(s), prior to disposing the artificial inclusion 458 onto the surface of the substrate portion. Followed by formation of the encapsulating portion 460, onto the surface of the substrate portion and on and around the artificial inclusion(s).

A pretreatment step of the surface of the substrate portion 454 can comprise various cutting steps, cleaning procedures and nucleation enhancing procedures. For example, in one embodiment the surface of the substrate portion is cut and polished to form a planar smooth surface, it may also be cleaned remove any amorphous carbon species, or non-diamond carbon species or debris that may be deposited thereon. A cleaning solution can also be utilized to clean the substrate portion prior to an optional nucleation treatment. Various nucleation treatments for purposes of increasing nucleation sites and or nucleation density were described in detail in previous sections of the disclosure, and are additionally incorporated herein. It is envisioned that the substrate portion is removed from the CVD reactor where it was grown, a cutting, polishing, machining, ablation, etching, milling, cleaning, nucleating or other such type process is conducted to prepare the substrate portion for firstly disposing a secondary gemstone thereon, and also for the deposition process of the encapsulating portion onto the substrate portion.

The methods disclosed herein further comprise a step of forming at least one cavity on the surface of the substrate portion and disposing the secondary gemstone within the formed at least one cavity on the surface of the substrate portion. Alternatively, in another embodiment, the secondary gemstone can be disposed on planar surface of the substrate portion, prior to commencement of the deposition and growth of the encapsulating portion. That is to say, a cavity is not formed in this embodiment, and the secondary gemstone is placed on a flat planar, optionally pretreated surface of the substrate portion.

Once the encapsulating portion is formed onto the substrate and onto and around the artificially embedded inclusion within the diamond, the bulk diamond structure can be formed into a final diamond by various means of cutting and polishing known in the art.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A cultured diamond comprising:
wherein the substrate portion and the encapsulating portion are bonded by covalent carbon to carbon bonds.

2. The cultured diamond of claim 1, wherein the substrate portion and/or encapsulating portion are formed by chemical vapor deposition (CVD), hot filament chemical vapor deposition (HFCVD), microwave plasma chemical vapor deposition (MPCVD), or a high pressure high temperature process (HPHT).

3. The cultured diamond of claim 1, wherein the human readable or machine readable indicia, comprise an image, a logo, a decorative design, a symbol, a pattern, an authentication identifier, a QR code, a bar code, an alphanumeric marking, written text, a personalized inscription, or a combination thereof.

4. The cultured diamond of claim 1, wherein the human readable or machine readable indicia is formed from:
deposition of the least one material layer on a planar surface of the substrate portion, or
deposition of the least one material layer on a non-planar surface of the substrate portion.

5. The cultured diamond of claim 1, wherein human readable or machine readable indicia is embedded by forming at least one cavity on the surface of the substrate portion; and
disposing a material within the formed at least one cavity on the surface of the substrate portion.

6. The cultured diamond of claim 1, wherein the human readable or machine readable indicia are formed through a process comprising laser ablation, wet etching, ion milling, ion beam irradiation, direct laser writing, microprinting, sputter deposition, maskless lithography, or a combination thereof.

7. The cultured diamond of claim 1, wherein the substrate portion and/or encapsulating portion comprise a dopant material incorporated during synthesis of the cultured diamond, the dopant material comprising nitrogen, boron, phosphorous, hydrogen, silicon, germanium, tin or a combination thereof.

8. A cultured diamond comprising:
wherein the substrate portion and encapsulating portion comprise a dopant material; and
wherein the substrate portion and the encapsulating portion are bonded by covalent carbon to carbon bonds.

9. The cultured diamond of claim 8, wherein the dopant material comprises nitrogen, boron, phosphorous, hydrogen, silicon, germanium, tin or a combination thereof.

10. The cultured diamond of claim 8, wherein the dopant material comprises two or more dopants.

11. The cultured diamond of claim 8, wherein the at least one human readable or machine readable indicia selected from an image, a logo, a decorative design, a symbol, a pattern, an authentication identifier, a QR code, a bar code, an alphanumeric marking, written text, a personalized inscription, or a combination thereof.

12. The cultured diamond of claim 8, wherein the cultured diamond undergoes a post-synthesis treatment comprising ion beam irradiation , thermal treatment, or a combination thereof.

13. The cultured diamond of claim 12, wherein the thermal treatment comprises heating the cultured diamond to a temperature between 700° C and 1000° C.

14. The cultured diamond of claim 9, wherein the dopant material is nitrogen.

15. The cultured diamond of claim 9, further comprising nitrogen-vacancy defects.

16. The cultured diamond of claim 15, wherein the nitrogen-vacancy defect comprise negatively charged nitrogen-vacancy defect, neutral nitrogen-vacancy defects, or a combination thereof.

17. The cultured diamond of claim 8, wherein the at least one human readable or machine readable indicia comprises graphite, graphene, a metallic compound, selected from gold, platinum, tungsten, or palladium, a metal oxide compound, fluorescent diamond particles, or a pigmented compound.

18. The cultured diamond of claim 8, wherein the human readable or machine readable indicia are formed through a process comprising, laser irradiation, laser ablation, wet etching, ion milling, ion beam irradiation, or a combination thereof.

19. The cultured diamond of claim 8, wherein the human readable or machine readable indicia are formed through direct laser writing, microprinting, or a combination thereof.

20. The cultured diamond of claim 8, wherein the human readable or machine readable indicia are formed through sputter deposition, maskless lithography, or a combination thereof.
